(19) United States
(12) Patent Application Publication
(10) Pub. No.: US 2015/0275033 A1
(43) Pub. Date: Oct. 1, 2015

(54) Aromatic Polyester Film

(71) Applicant: Ticona LLC, Florence, KY (US)

(72) Inventors: Yi Li, Florence, KY (US); Kamlesh P. Nair, Florence, KY (US); Prabuddha Bansal, Florence, KY (US); Tsz Ming Tsang, Cincinnati, OH (US); James P. Shepherd, Independence, KY (US)

(21) Appl. No.: 14/526,566

(22) Filed: Oct. 29, 2014

Related U.S. Application Data
(60) Provisional application No. 61/970,494, filed on Mar. 26, 2014.

(51) Int. Cl. C09D 167/04; B05D 3/02; B05D 7/24; H05K 3/00

(52) U.S. Cl. CPC C09D 167/04; H05K 3/007; B05D 3/0254; B05D 7/24

(57) ABSTRACT

A film containing an aromatic polyester with aromatic biphenyl repeating units having the following general Formula I:

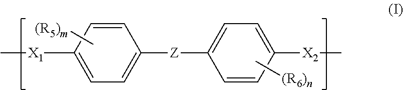

is provided. The film is annealed and exhibits a relatively isotropic tensile property.

### RELATED APPLICATIONS

The present application claims priority to U.S. Provisional Application Ser. No. 61/970,494, filed on Mar. 24, 2014, which is incorporated herein in its entirety by reference thereto.

### BACKGROUND OF THE INVENTION

Flexible printed circuit boards are increasingly being used in high density, small electronic components. Such circuit boards are typically produced from a “copper clad laminate” that contains a copper foil and an insulating film. However, the laminate often curls during heat treatment due to the relatively poor heat resistance of the polymers used to form the film. In this regard, liquid crystalline polyesters have been suggested for use in forming the insulating film due to their relatively high degree of heat resistance. Nevertheless, one of the problems in successfully incorporating these types of polymers into flexible printed circuit boards is that they are not soluble in most solvents, and thus cannot be readily cast into a film. Various attempts have been made to solve this problem. For example, one liquid crystalline polyester that has been proposed for producing films is formed from 2-hydroxy-6-naphthoic acid (“HNA”), 2,6-naphthanlenedicarboxylic acid (“NDA”), and 4,4′-dihydroxydiphenyl ether. Unfortunately, one of the problems with such films is that they tend to be relatively brittle and possess relatively poor mechanical properties. As such, a need exists for an aromatic polyester film having improved properties.

### SUMMARY OF THE INVENTION

In accordance with one embodiment of the present invention, a film is disclosed that comprises an aromatic polyester that contains aromatic biphenyl repeating units having the following general Formula I:

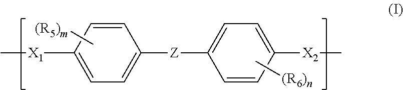

wherein,
R₅ and R₆ are independently halo, haloalkyl, alkyl, alkenyl, aryl, heteroaryl, cycloalkyl, or heterocyclyl;
m and n are independently from 0 to 4;
X₁ and X₂ are independently O, C(O), NH, C(O)HN, or NHC(O); and
Z is O or SO₂.

The film is annealed, and it also exhibits a tensile property value in the machine direction and the cross-machine direction, the ratio of the tensile property value in the machine direction to the tensile property value in the cross-machine direction being from about 0.7 to about 1.3.

In accordance with another embodiment of the present invention, a method for forming a film is disclosed that comprises coating a substrate with a polymer solution that includes an aromatic polyester and a solvent system to form the film, and thereafter annealing the film. The aromatic polyester contains aromatic biphenyl repeating units having the following general Formula I:

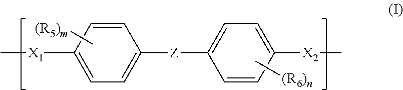

wherein,
R₅ and R₆ are independently halo, haloalkyl, alkyl, alkenyl, aryl, heteroaryl, cycloalkyl, or heterocyclyl;
m and n are independently from 0 to 4;
X₁ and X₂ are independently O, (O), NH, C(O)HN, or NHC(O); and
Z is O or SO₂.

Other features and aspects of the present invention are set forth in greater detail below.

### DETAILED DESCRIPTION

It is to be understood that the terminology used herein is for the purpose of describing particular embodiments only and is not intended to limit the scope of the present invention.

“Alkyl” refers to monovalent saturated aliphatic hydrocarbyl groups having from 1 to 10 carbon atoms and, in some embodiments, from 1 to 6 carbon atoms. “C_{x-y}alkyl” refers to alkyl groups having from x to y carbon atoms. This term includes, by way of example, linear and branched hydrocarbyl groups such as methyl (CH₃), ethyl (CH₃CH₂), n-propyl (CH₃CH₂CH₂), isopropyl ((CH₃)₂CH), n-butyl (CH₃CH₂CH2CH₂), isobutyl ((CH₃)₂CHCH₂), sec-butyl ((CH₃)(CH₃CH₂)CH), t-butyl ((CH₃)₃C), n-pentyl (CH₃CH₂CH₂CH₂CH₂), and neopentyl ((CH₃)₃CCH₂).

“Alkenyl” refers to a linear or branched hydrocarbyl group having from 2 to 10 carbon atoms and in some embodiments from 2 to 6 carbon atoms or 2 to 4 carbon atoms and having at least 1 site of vinyl unsaturation (>C═C<). For example, (Cₓ-C_{y})alkenyl refers to alkenyl groups having from x to y carbon atoms and is meant to include for example, ethenyl, propenyl, 1,3-butadienyl, and so forth.

“Alkynyl” refers to refers to a linear or branched monovalent hydrocarbon radical containing at least one triple bond. The term “alkynyl” may also include those hydrocarbyl groups having other types of bonds, such as a double bond and a triple bond.

“Aryl” refers to an aromatic group of from 3 to 14 carbon atoms and no ring heteroatoms and having a single ring (e.g., phenyl) or multiple condensed (fused) rings (e.g., naphthyl or anthryl). For multiple ring systems, including fused, bridged, and spiro ring systems having aromatic and non-aromatic rings that have no ring heteroatoms, the term “Aryl” applies when the point of attachment is at an aromatic carbon atom (e.g., 5,6,7,8 tetrahydronaphthalene-2-yl is an aryl group as its point of attachment is at the 2-position of the aromatic phenyl ring).

“Cycloalkyl” refers to a saturated or partially saturated cyclic group of from 3 to 14 carbon atoms and no ring heteroatoms and having a single ring or multiple rings including fused, bridged, and Spiro ring systems. For multiple ring systems having aromatic and non-aromatic rings that have no ring heteroatoms, the term “cycloalkyl” applies when the point of attachment is at a non-aromatic carbon atom (e.g., 5,6,7,8,-tetrahydronaphthalene-5-yl). The term “cycloalkyl” includes cycloalkenyl groups, such as adamantyl, cyclopropyl, cyclobutyl, cyclopentyl, cyclooctyl, and cyclohexenyl. The term “cycloalkenyl” is sometimes employed to refer to a partially saturated cycloalkyl ring having at least one site of >C═C< ring unsaturation.

“Halo” or “halogen” refers to fluoro, chloro, bromo, and iodo,

“Haloalkyl” refers to substitution of alkyl groups with 1 to 5 or in some embodiments 1 to 3 halo groups.

“Heteroaryl” refers to an aromatic group of from 1 to 14 carbon atoms and 1 to 6 heteroatoms selected from oxygen, nitrogen, and sulfur and includes single ring (e.g., imidazolyl) and multiple ring systems (e.g., benzimidazol-2-yl and benzimidazol-6-yl). For multiple ring systems, including fused, bridged, and spiro ring systems having aromatic and non-aromatic rings, the term “heteroaryl” applies if there is at least one ring heteroatom and the point of attachment is at an atom of an aromatic ring (e.g., 1,2,3,4-tetrahydroquinolin-6-yl and 5,6,7,8-tetrahydroquinolin-3-yl). In some embodiments, the nitrogen and/or the sulfur ring atom(s) of the heteroaryl group are optionally oxidized to provide for the N oxide (N→O), sulfinyl, or sulfonyl moieties. Examples of heteroaryl groups include, but are not limited to, pyridyl, furanyl, thienyl, thiazolyl, isothiazolyl, triazolyl, imidazolyl, imidazolinyl, isoxazolyl, pyrrolyl, pyrazolyl, pyridazinyl, pyrimidinyl, purinyl, phthalazyl, naphthylpryidyl, benzofuranyl, tetrahydrobenzofuranyl, isobenzofuranyl, benzothiazolyl, benzoisothiazolyl, benzotriazolyl, indolyl, isoindolyl, indolizinyl, dihydroindolyl, indazolyl, indolinyl, benzoxazolyl, quinolyl, isoquinolyl, quinolizyl, quianazolyl, quinoxalyl, tetrahydroquinolinyl, isoquinolyl, quinazolinonyl, benzimidazolyl, benzisoxazolyl, benzothienyl, benzopyridazinyl, pteridinyl, carbazolyl, carbolinyl, phenanthridinyl, acridinyl, phenanthrolinyl, phenazinyl, phenoxazinyl, phenothiazinyl, and phthalimidyl.

“Heterocyclic” or “heterocycle” or “heterocycloalkyl” or “heterocyclyl” refers to a saturated or partially saturated cyclic group having from 1 to 14 carbon atoms and from 1 to 6 heteroatoms selected from nitrogen, sulfur, or oxygen and includes single ring and multiple ring systems including fused, bridged, and Spiro ring systems. For multiple ring systems having aromatic and/or non-aromatic rings, the terms “heterocyclic”, “heterocycle”, “heterocycloalkyl”, or “heterocyclyl” apply when there is at least one ring heteroatom and the point of attachment is at an atom of a non-aromatic ring (e.g., decahydroquinolin-6-yl), In some embodiments, the nitrogen and/or sulfur atom(s) of the heterocyclic group are optionally oxidized to provide for the N oxide, sulfinyl, sulfonyl moieties. Examples of heterocyclyl groups include, but are not limited to, azetidinyl, tetrahydropyranyl, piperidinyl, N-methylpiperidin-3-yl, piperazinyl, N-methylpyrrolidin-3-yl, 3-pyrrolidinyl, 2-pyrrolidon-1-yl, morpholinyl, thiomorpholinyl, imidazolidinyl, and pyrrolidinyl.

It should be understood that the aforementioned definitions encompass unsubstituted groups, as well as groups substituted with one or more other functional groups as is known in the art. For example, an aryl, heteroaryl, cycloalkyl, or heterocyclyl group may be substituted with from 1 to 8, in some embodiments from 1 to 5, in some embodiments from 1 to 3, and in some embodiments, from 1 to 2 substituents selected from alkyl, alkenyl, alkynyl, alkoxy, acyl, acylamino, acyloxy, amino, quaternary amino, amide, imino, amidino, aminocarbonylamino, amidinocarbonylamino, aminothiocarbonyl, aminocarbonylamino, aminothiocarbonylamino, aminocarbonyloxy, aminosulfonyl, aminosulfonyloxy, aminosulfonylamino, aryl, aryloxy, arylthio, azido, carboxyl, carboxyl ester, (carboxyl ester)amino, (carboxyl ester)oxy, cyano, cycloalkyl, cycloalkyloxy, cycloalkylthio, guanidino, halo, haloalkyl, haloalkoxy, hydroxy, hydroxyamino, alkoxyamino, hydrazino, heteroaryl, heteroaryloxy, heteroarylthio, heterocyclyl, heterocyclyloxy, heterocyclylthio, nitro, oxo, oxy, thione, phosphate, phosphonate, phosphinate, phosphonamidate, phosphorodiamidate, phosphoramidate monoester, cyclic phosphoramidate, cyclic phosphorodiamidate, phosphoramidate diester, sulfate, sulfonate, sulfonyl, substituted sulfonyl, sulfonyloxy, thioacyl, thiocyanate, thiol, alkylthio, etc., as well as combinations of such substituents. When incorporated into the polymer of the present invention, such substitutions may be pendant or grafted groups, or may themselves form part of the polymer backbone.

It is to be understood by one of ordinary skill in the art that the present discussion is a description of exemplary embodiments only, and is not intended as limiting the broader aspects of the present invention.

Generally speaking, the present invention is directed to a film that includes an aromatic polyester containing aromatic biphenyl repeating units of Formula I:

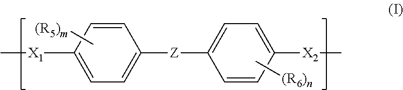

wherein,
R₅ and R₆ are independently halo, haloalkyl, alkyl, alkenyl, aryl, heteroaryl, cycloalkyl, or heterocyclyl;
m and n are independently from 0 to 4, in some embodiments from 0 to 1, and in one particular embodiment, 0;
X₁ and X₂ are independently O, C(O), NH, C(O)HN, or NHC(O); and
Z is O or SO₂.

By selectively controlling the nature of the repeating units, the present inventors have discovered the resulting aromatic polyester can be generally soluble or dispersible in certain solvents, which allows for the polyester to be formed into a solution and thereafter formed into a film. Without intending to be limited by theory, it is believed that the aromatic repeating units can sufficiently disrupt the highly crystalline and linear nature of the polymer backbone without having a significantly adverse impact on other properties of the polymer. Thus, the ability of the resulting polymer to be dissolved or dispersed in various solvents for forming can be enhanced without sacrificing performance. When dissolved in the solvent system, the polymer may exhibit amorphous-like properties in that it becomes transparent and lacks an identifiable melting point. Yet, the present inventors have discovered by annealing the film under certain conditions, the polymer can become thermotropic in nature and possess a highly aligned, rod-like structure. Thus, contrary to conventional melt processed liquid crystalline films, the resulting film of the present invention may exhibit macroscopically “isotropic” tensile properties in that the ratio of the value of at least one tensile property (e.g., tensile strength, peak elongation, Young's modulus, etc.) of the film in the machine direction (“MD”) to the value of the tensile property in the cross-machine direction (“CD”) is from about 0.7 to about 1.3, in some embodiments from about 0.8 to about 1.2, and in some embodiments, from about 0.9 to about 1.1 (e.g., about 1.0).

The film may, for example, exhibit relatively high peak elongation values in the machine and/or cross-machine direction, such as about 5% or more, in some embodiments about 10% or more, and in some embodiments, from about 15% to about 50%. In addition, the film may exhibit a Young's modulus of elasticity in the machine direction and/or cross-machine direction of from about 500 to about 10,000 MPa, in some embodiments from about 1,000 to about 6,000 MPa, and in some embodiments, from about 1,500 to about 3,000 MPa. Despite having good modulus and elongation values, the film of the present invention is nevertheless able to retain good mechanical strength. For example, the film of the present invention may exhibit a tensile strength (stress) in the machine direction and/or cross-machine direction of from about 15 to about 300 Megapascals (MPa), in some embodiments from about 30 to about 200 MPa, and in some embodiments, from about 50 to about 150 MPa. Surprisingly, such good properties can be achieved even though the film has a very low thickness. For example, the thickness of the film may be about 500 micrometers or less, in some embodiments from about 1 to about 250 micrometers, in some embodiments from about 2 to about 100 micrometers, and in some embodiments, from about 5 to about 50 micrometers.

Various embodiments of the present invention will now be described in more detail.

### I. Film

As indicated above, the film of the present invention includes an aromatic polyester containing aromatic biphenyl repeating units having the structure set forth in Formula I above. The nature and relative concentration of the aromatic biphenyl repeating units are generally selected to achieve the desired solubility without sacrificing mechanical properties. For example, the aromatic biphenyl repeating units of Formula I may constitute from about 5 mol. % to about 50 mol. %, in some embodiments from about 10 mol. % to about 40 mol. %, and in some embodiments, from about 15 mol. % to about 30 mol. % of the polymer. Furthermore, in one particular embodiment, m and n are 0 in Formula I such that the biphenyl repeating unit has the following Formula (III):

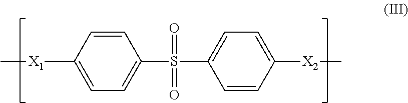

wherein, X₁ and X₂ are independently O, C(O), NH, C(O)HN, or NHC(O). For example, X₁ and/or X₂ may be O and/or NH.

The repeating units represented in Formula I and/or Formula Ill above may be derived from a variety of different biphenyl precursor monomers, including, for example, biphenyl alcohols (e.g., 4-(4-hydroxyphenyl)-sulfonylphenol, 4-(4-aminophenyl)sulfonylphenol, 4-(4-aminophenoxy)phenol, 4-(4-hydroxyphenoxy)-phenol, etc.); biphenyl amines (e.g., 4-(4-aminophenyl)sulfonylaniline, 4-(4-aminophenoxy)aniline, etc.); biphenyl acids (e.g., 4-(4-carboxyphenyl)-sulfonylbenzoic acid, 4-(4-formylphenoxy)benzaldehyde, etc.); biphenyl amides (e.g., 4-(4-carbamoylphenyl)sulfonylbenzamide, N[4-(4-formamidophenyl)-sulfonylphenyl]formamide, 4-(4-carbamoylphenoxylbenzamide, etc.); and so forth, as well as combinations thereof.

In addition to the biphenyl repeating units of Formula I, the aromatic polyester may also contain one or more aromatic ester repeating units, typically in an amount of from about 50 mol. % to about 99 mol. %, in some embodiments from about 55 mol. % to about 98 mol. %, and in some embodiments, from about 60 mol. % to about 95 mol. % of the polymer. The resulting copolymer may have any desired copolymer configuration known in the art, such as a block copolymer, grafted copolymer, random copolymer, etc.

The aromatic ester repeating units may be generally represented by the following Formula (II):

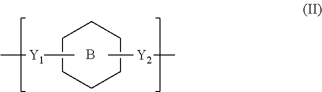

wherein,
ring B is a substituted or unsubstituted 6-membered aryl group (e.g., 1,4-phenylene or 1,3-phenylene), a substituted or unsubstituted 6-membered aryl group fused to a substituted or unsubstituted 5- or 6-membered aryl group (e.g., 2,6-naphthalene), or a substituted or unsubstituted 6-membered aryl group linked to a substituted or unsubstituted 5- or 6-membered aryl group (e.g., 4,4-biphenylene); and
Y₁ and Y₂ are independently O, C(O), NH, C(O)HN, or NHC(O), wherein at least one of Y₁ and Y₂ are C(O).

Examples of aromatic ester repeating units that are suitable for use in the present invention may include, for instance, aromatic dicarboxylic repeating units (Y₁ and Y₂ in Formula II are C(O)), aromatic hydroxycarboxylic repeating units (Y₁ is O and Y₂ is C(O) in Formula II), as well as various combinations thereof.

Aromatic dicarboxylic repeating units, for instance, may be employed that are derived from aromatic dicarboxylic acids, such as terephthalic acid, isophthalic acid, 2,6-naphthalenedicarboxylic acid, diphenyl ether-4,4′-dicarboxylic acid, 1,6-naphthalenedicarboxylic acid, 2,7-naphthalenedicarboxylic acid, 4,4′-dicarboxybiphenyl, bis(4-carboxyphenyl)ether, bis(4-carboxyphenyl)butane, bis(4-carboxyphenyl)ethane, bis(3-carboxyphenyl)ether, bis(3-carboxyphenyl)ethane, etc., as well as alkyl, alkoxy, aryl and halogen substituents thereof, and combinations thereof. Particularly suitable aromatic dicarboxylic acids may include, for instance, terephthalic acid (“TA”) and isophthalic acid (“IA”). When employed, repeating units derived from aromatic dicarboxylic acids (e.g., IA and/or TA) typically constitute from about 5 mol. % to about 60 mol. %, in some embodiments from about 10 mol. % to about 55 mol. %, and in some embodiments, from about 15 mol. % to about 50% of the polymer.

Aromatic hydroxycarboxylic repeating units may also be employed that are derived from aromatic hydroxycarboxylic acids, such as, 4-hydroxybenzoic acid; 4-hydroxy-4′-biphenylcarboxylic acid; 2-hydroxy-6-naphthoic acid; 2-hydroxy-5-naphthoic acid; 3-hydroxy-2-naphthoic acid; 2-hydroxy-3-naphthoic acid; 4′-hydroxyphenyl-4-benzoic acid; 3′-hydroxyphenyl-4-benzoic acid; 4′-hydroxyphenyl-3-benzoic acid, etc., as well as alkyl, alkoxy, aryl and halogen substituents thereof, and combination thereof. One particularly suitable aromatic hydroxycarboxylic acid is 4-hydroxybenzoic acid (“HBA”). When employed, repeating units derived from hydroxycarboxylic acids (e.g., HBA) typically constitute from about 1 mol. % to about 70 mol. %, in some embodiments from about 5 mol. % to about 65 mol. %, and in some embodiments, from about 10 mol. % to about 50% of the polymer.

Although by no means required, it may be desirable in certain embodiments to employ an aromatic polyester that is “low naphthenic” to the extent that it contains a minimal content of repeating units derived from naphthenic hydroxycarboxylic acids and naphthenic dicarboxylic acids, such as naphthalene-2,6-dicarboxylic acid (“NDA”), 6-hydroxy-2-naphthoic acid (“HNA”), or combinations thereof. That is, the total amount of repeating units derived from naphthenic hydroxycarboxylic and/or dicarboxylic acids (e.g., NDA, HNA, or a combination of HNA and NDA) is typically no more than about 60 mol. %, in some embodiments, no more than about 50 mol. %, in some embodiments no more than about 35 mol. %, in some embodiments no more than about 30 mol. %, in some embodiments no more than about 25 mol. %, in some embodiments no more than about 20 mol. %, in some embodiments no more than about 15 mol. %, and in some embodiments, from 0 mol. % to about 10 mol. % of the polymer (e.g., 0 mol. %). Despite the absence of a high level of conventional naphthenic acid repeating units, the present inventors have discovered that selective control over the type and relative concentration of the biphenyl repeating units can lead to “low naphthenic” polymers that are not only soluble in the solvent system, but also capable of exhibiting good mechanical properties.

Other repeating units may also be employed in the polymer. In certain embodiments, for instance, repeating units may be employed that are derived from aromatic diols, such as hydroquinone, resorcinol, 2,6-dihydroxynaphthalene, 2,7-dihydroxynaphthalene, 1,6-dihydroxynaphthalene, 4,4′-dihydroxybiphenyl (or 4,4′-biphenol), 3,3′-dihydroxybiphenyl, 3,4′-dihydroxybiphenyl, 4,4′-dihydroxybiphenyl ether, bis(4-hydroxyphenyl)ethane, etc., as well as alkyl, alkoxy, aryl and halogen substituents thereof, and combinations thereof. Particularly suitable aromatic diols may include, for instance, hydroquinone (“HQ”) and 4,4′-biphenol (“BP”). When employed, repeating units derived from aromatic diols (e.g., HQ and/or BP) typically constitute from about 1 mol. % to about 30 mol. %, in some embodiments from about 2 mol. % to about 25 mol. %, and in some embodiments, from about 5 mol. % to about 20% of the polymer. Repeating units may also be employed, such as those derived from aromatic amides (e.g., acetaminophen (“APAP”)) and/or aromatic amines (e.g., 4-aminophenol (“AP”), 3-aminophenol, 1,4-phenylenediamine, 1,3-phenylenediamine, etc.). When employed, repeating units derived from aromatic amides (e.g., APAP) and/or aromatic amines (e.g., AP) typically constitute from about 0.1 mol. % to about 20 mol. %, in some embodiments from about 0.5 mol. % to about 15 mol. %, and in some embodiments, from about 1 mol. % to about 10% of the polymer. It should also be understood that various other monomeric repeating units may be incorporated into the polymer. For instance, in certain embodiments, the polymer may contain one or more repeating units derived from non-aromatic monomers, such as aliphatic or cycloaliphatic hydroxycarboxylic acids, dicarboxylic acids (e.g., cyclohexane dicarboxylic acid), diols, amides, amines, etc. Of course, in other embodiments, the polymer may be “wholly aromatic” in that it lacks repeating units derived from non-aromatic (e.g., aliphatic or cycloaliphatic) monomers.

In one particular embodiment, for example, the aromatic polyester may be formed from repeating units derived from a biphenyl sulfonyl alcohol and/or biphenyl sulfonyl amine (e.g., 4-(4-hydroxyphenyl)sulfonylphenol, or 4-(4-aminophenyl)-sulfonylaniline), 4-hydroxybenzoic acid (“HBA”), and terephthalic acid (“TA”) and/or isophthalic acid (“IA”), as well as various other optional constituents. The repeating units derived from the sulfonyl compound may constitute from about 5 mol,% to about 50 mol. %, in some embodiments from about 10 mol. % to about 40 mol. %, and in some embodiments, from about 15 mol. % to about 30 mol. %. The repeating units derived from 4-hydroxybenzoic acid (“HBA”) may constitute from about 5 mol. % to about 70 mol. %, in some embodiments from about 10 mol. % to about 65 mol. %, and in some embodiments, from about 15 mol. % to about 50% of the polymer. The repeating units derived from terephthalic acid (“TA”) and/or isophthalic acid (“IA”) may likewise constitute from about 5 mol. % to about 40 mol. %, in some embodiments from about 10 mol. % to about 35 mol. %, and in some embodiments, from about 15 mol. % to about 35% of the polymer. Other possible repeating units may include those derived from 4,4′-biphenol (“BP”), hydroquinone (“HQ”), and/or acetaminophen (“APAP”). In certain embodiments, for example, repeating units derived from BP, HQ, and/or APAP may each constitute from about 1 mol. % to about 30 mol. %, in some embodiments from about 2 mol. % to about 25 mol. %, and in some embodiments, from about 3 mol. % to about 20 mol. % when employed. If desired, the polymer may also contain a relatively low amount of repeating units derived from naphthenic monomers (6-hydroxy-2-naphthoic acid (“HNA”) or 2,6-naphthalenedicarboxylic acid (“NDA”) within the ranges noted above.

Regardless of the particular constituents and nature of the polymer, the aromatic polyester may be prepared by initially introducing the aromatic monomer(s) used to form the ester repeating units (e.g., aromatic hydroxycarboxylic acid, aromatic dicarboxylic acid, etc.) and/or other repeating units (e.g., aromatic diol, aromatic amide, aromatic amine, etc.) into a reactor vessel to initiate a polycondensation reaction. The particular conditions and steps employed in such reactions are well known, and may be described in more detail in U.S. Pat. No. 4,161,470 to Calundann; U.S. Pat. No. 5,616,680 to Linstid, III, et al.; U.S. Pat. No. 6,114,492 to Linstid, III, et al.; U.S. Pat. No. 6,514,611 to Shepherd, et al.; and WO 2004/058851 to Waggoner. The vessel employed for the reaction is not especially limited, although it is typically desired to employ one that is commonly used in reactions of high viscosity fluids. Examples of such a reaction vessel may include a stirring tank-type apparatus that has an agitator with a variably-shaped stirring blade, such as an anchor type, multistage type, spiral-ribbon type, screw shaft type, etc., or a modified shape thereof. Further examples of such a reaction vessel may include a mixing apparatus commonly used in resin kneading, such as a kneader, a roll mill, a Banbury mixer, etc.

If desired, the reaction may proceed through the acetylation of the monomers as known the art. This may be accomplished by adding an acetylating agent (e.g., acetic anhydride) to the monomers. Acetylation is generally initiated at temperatures of about 90° C. During the initial stage of the acetylation, reflux may be employed to maintain vapor phase temperature below the point at which acetic acid byproduct and anhydride begin to distill. Temperatures during acetylation typically range from between 90° C. to 150° C., and in some embodiments, from about 110° C. to about 150° C. If reflux is used, the vapor phase temperature typically exceeds the boiling point of acetic acid, but remains low enough to retain residual acetic anhydride. For example, acetic anhydride vaporizes at temperatures of about 140° C. Thus, providing the reactor with a vapor phase reflux at a temperature of from about 110° C. to about 130° C. is particularly desirable. To ensure substantially complete reaction, an excess amount of acetic anhydride may be employed. The amount of excess anhydride will vary depending upon the particular acetylation conditions employed, including the presence or absence of reflux. The use of an excess of from about 1 to about 10 mole percent of acetic anhydride, based on the total moles of reactant hydroxyl groups present is not uncommon.

Acetylation may occur in in a separate reactor vessel, or it may occur in situ within the polymerization reactor vessel. When separate reactor vessels are employed, one or more of the monomers may be introduced to the acetylation reactor and subsequently transferred to the polymerization reactor. Likewise, one or more of the monomers may also be directly introduced to the reactor vessel without undergoing pre-acetylation.

The biphenyl precursor monomer (e.g., biphenyl alcohol, acid, amine, amide, etc.) may also be added to the polymerization apparatus. Although it may be introduced at any time, it is typically desired to apply the biphenyl monomer before melt polymerization has been initiated, and typically in conjunction with the other aromatic precursor monomers for the polymer. The relative amount of the biphenyl monomer added to the reaction mixture may be selected to help achieve a balance between solubility and mechanical properties as described above. In most embodiments, for example, biphenyl monomer(s) constitute from about 0.1 wt. % to about 30 wt. %, in some embodiments from about 0.5 wt. % to about 25 wt. %, and in some embodiments, from about 1 wt. % to about 20 wt. % of the reaction mixture.

In addition to the monomers and optional acetylating agents, other components may also be included within the reaction mixture to help facilitate polymerization. For instance, a catalyst may be optionally employed, such as metal salt catalysts (e.g., magnesium acetate, tin (I) acetate, tetrabutyl titanate, lead acetate, sodium acetate, potassium acetate, etc.) and organic compound catalysts (e.g., N-methylimidazole). Such catalysts are typically used in amounts of from about 50 to about 500 parts per million based on the total weight of the recurring unit precursors. When separate reactors are employed, it is typically desired to apply the catalyst to the acetylation reactor rather than the polymerization reactor, although this is by no means a requirement.

The reaction mixture is generally heated to an elevated temperature within the polymerization reactor vessel to initiate melt polycondensation of the reactants. Polycondensation may occur, for instance, within a temperature range of from about 210° C. to about 400° C., and in some embodiments, from about 250° C. to about 350° C. For instance, one suitable technique for forming the aromatic polyester may include charging precursor monomers and acetic anhydride into the reactor, heating the mixture to a temperature of from about 90° C. to about 150° C. to acetylize a hydroxyl group of the monomers (e.g., forming acetoxy), and then increasing the temperature to a temperature of from about 210° C. to about 400° C. to carry out melt polycondensation. As the final polymerization temperatures are approached, volatile byproducts of the reaction (e.g., acetic acid) may also be removed so that the desired molecular weight may be readily achieved. The reaction mixture is generally subjected to agitation during polymerization to ensure good heat and mass transfer, and in turn, good material homogeneity. The rotational velocity of the agitator may vary during the course of the reaction, but typically ranges from about 10 to about 100 revolutions per minute (“rpm”), and in some embodiments, from about 20 to about 80 rpm. To build molecular weight in the melt, the polymerization reaction may also be conducted under vacuum, the application of which facilitates the removal of volatiles formed during the final stages of polycondensation. The vacuum may be created by the application of a suctional pressure, such as within the range of from about 5 to about 30 pounds per square inch (“psi”), and in some embodiments, from about 10 to about 20 psi.

Following melt polymerization, the molten polymer may be discharged from the reactor, typically through an extrusion orifice fitted with a die of desired configuration, cooled, and collected. Commonly, the melt is discharged through a perforated die to form strands that are taken up in a water bath, pelletized and dried. The resin may also be in the form of a strand, granule, or powder. While unnecessary, it should also be understood that a subsequent solid phase polymerization may be conducted to further increase molecular weight. When carrying out solid-phase polymerization on a polymer obtained by melt polymerization, it is typically desired to select a method in which the polymer obtained by melt polymerization is solidified and then pulverized to form a powdery or flake-like polymer, followed by performing solid polymerization method, such as a heat treatment in a temperature range of 200° C. to 350° C. under an inert atmosphere (e.g., nitrogen).

Regardless of the particular method employed, the resulting aromatic polyester may have a relatively high melting temperature. For example, the melting temperature of the polymer may be from about 250° C. to about 385° C., in some embodiments from about 280° C. to about 380° C., in some embodiments from about 290° C. to about 360° C., and in some embodiments, from about 300° C. to about 350° C. Of course, in some cases, the polymer may not exhibit a distinct melting temperature when determined according to conventional techniques (e.g., DSC). The polymer may also have a relatively high melt viscosity, such as about 20 Pa-s or more, in some embodiments about 50 Pa-s or more, and in some embodiments, from about 75 to about 500 Pa-s, as determined at a shear rate of 1000 seconds⁻¹ and temperatures at least 20° C. above the melting temperature (e.g., 320° C. or 350° C.) in accordance with ISO Test No. 11443 (equivalent to ASTM Test No. 1238-70). Further, the polymer typically has a number average molecular weight (Mₙ) of about 2,000 grams per mole or more, in some embodiments from about 4,000 grams per mole or more, and in some embodiments, from about 5,000 to about 50,000 grams per mole. Of course, it is also possible to form polymers having a lower molecular weight, such as less than about 2,000 grams per mole, using the method of the present invention. The intrinsic viscosity of the polymer, which is generally proportional to molecular weight, may also be relatively high. For example, the intrinsic viscosity may be about 1 deciliters per gram (“dL/g”) or more, in some embodiments about 2 dL/g or more, in some embodiments from about 3 to about 20 dL/g, and in some embodiments from about 4 to about 15 dL/g. Intrinsic viscosity may be determined in accordance with ISO-1628-5 using a 50/50 (v/v) mixture of pentafluorophenol and hexafluoroisopropanol, as described in more detail below.

If desired, the film may also employ one or more additives. Examples of such additives may include, for instance, viscosity modifiers, antimicrobials, pigments, antioxidants, stabilizers, surfactants, waxes, flow promoters, solid solvents, inorganic and organic fillers, and other materials added to enhance properties and processibility. For example, a filler material may be incorporated within the film to enhance strength. A filler composition can include a filler material such as a fibrous filler and/or a mineral filler and optionally one or more additional additives as are generally known in the art. Mineral fillers may, for instance, be employed to help achieve the desired mechanical properties and/or appearance.

Clay minerals may be particularly suitable for use in the present invention. Examples of such clay minerals include, for instance, talc (Mg₃Si₄O₁₀(OH)₂), halloysite (Al₂Si₂O₅(OH)₄), kaolinite (Al₂Si₂O₅(OH)₄), illite ((K,H₃O)(Al,Mg,Fe)₂(Si,Al)₄O₁₀[(OH)₂,(H₂O)]), montmorillonite (Na,Ca)_{0.33}(Al,Mg)₂Si₄O₁₀(OH)₂.nH₂O), vermiculite ((MgFe,Al)₃(Al,Si)₄O₁₀(OH)₂.4H₂O), palygorskite ((Mg,Al)₂Si₄O₁₀(OH).4(H₂O)), pyrophyllite (Al₂Si₄O₁₀(OH₂)₂), etc., as well as combinations thereof. In lieu of, or in addition to, clay minerals, still other mineral fillers may also be employed. For example, other suitable fillers may include boron nitride, calcium silicate, aluminum silicate, mica, diatomaceous earth, wollastonite, alumina, silica, titanium dioxide, calcium carbonate, and so forth. Mica, for instance, may be particularly suitable. There are several chemically distinct mica species with considerable variance in geologic occurrence, but all have essentially the same crystal structure. As used herein, the term “mica” is meant to generically include any of these species, such as muscovite (KAl₂(AlSi₃)O₁₀(OH)₂), biotite (K(Mg,Fe)₃(AlSi₃)O₁₀(OH)₂), phlogopite (KMg₃(AlSi₃)O₁₀(OH)₂), lepidolite (K(Li,Al)₂₋₃(AlSi₃)O₁₀(OH)₂), glauconite (K,Na)(Al,Mg,Fe)₂(Si,Al)₄O₁₀(OH)₂), etc., as well as combinations thereof. Nano-sized inorganic filler particles (e.g., diameter of about 100 nanometers or less) may also be employed in certain embodiments to help improve the flow properties of the composition. Examples of such particles may include, for instance, nanoclays, nanosilica, nanoalumina, etc. In yet another embodiment, inorganic hollow spheres (e.g., hollow glass spheres) may also be employed in the composition to help decrease the dielectric constant of the composition for certain applications.

Fibers may also be employed as a filler material to further improve the mechanical properties. Such fibers generally have a high degree of tensile strength relative to their mass. For example, the ultimate tensile strength of the fibers (determined in accordance with ASTM D2101) is typically from about 1,000 to about 15,000 Megapascals (“MPa”), in some embodiments from about 2,000 MPa to about 10,000 MPa, and in some embodiments, from about 3,000 MPa to about 6,000 MPa. To help maintain an insulating property, which is often desirable for use in electronic applications, the high strength fibers may be formed from materials that are also generally insulating in nature, such as glass, ceramics (e.g., alumina or silica), aramids (e.g., Kevlar® are marketed by E. I. Du Pont de Nemours, Wilmington, Del.), polyolefins, polyesters, etc., as well as mixtures thereof. Glass fibers are particularly suitable, such as E-glass, A-glass, C-glass, D-glass, AR-glass, R-glass, S1-glass, S2-glass, etc., and mixtures thereof.

### II. Formation of the Film

As indicated above, the aromatic polyester of the present invention is generally soluble or dispersible in certain solvents, thereby allowing it to be formed into a solution for film formation. Thus, while any of a variety of film-forming techniques may generally be employed, one particular embodiment of the present invention involves forming the film through a technique that includes applying a solution of the aromatic polyester onto a substrate.

The “solubility” of the aromatic polyester may be from about 1% to about 50%, in some embodiments from about 2% to about 40%, and in some embodiments, from about 5% to about 30%. As discussed in more detail below, the “solubility” for a given polymer is calculated by dividing the maximum weight of the polymer that can be added to a solvent system without any visible macroscopic phase separation by the weight of the solvent system, and then multiplying this value by 100. The resulting solution also typically has a relatively low solution viscosity, such as from about 1 to about 3,500 centipoise, in some embodiments from about 2 to about 1,000 centipoise, and in some embodiments, from about 5 to about 100 centipoise, as determined at a temperature of 22° C. using a Brookfield viscometer (e.g., spindle #2 or #4 and speed of 100 rpm). The polymer solution may also be relatively “stable” in that it does not undergo a substantial degree of gelation over time. In this regard, the stability of the solution may be evidenced by the fact that the solution can maintain its viscosity within the ranges noted above for a period of forty-eight (48) hours after being heated at 160° C. for 4 hours.

A wide variety of solvents can be employed in the solvent system used to form the polymer solution. Suitable solvents may include, for instance, aprotric solvents, protic solvents, as well as mixtures thereof. Examples of aprotic solvents may include organic solvents, such as halogen-containing solvents (e.g., methylene chloride, 1-chlorobutane, chlorobenzene, 1,1-dichloroethane, 1,2-dichloroethane, chloroform, and 1,1,2,2-tetrachloroethane); ether solvents (e.g., diethyl ether, tetrahydrofuran, and 1,4-dioxane); ketone solvents (e.g., acetone and cyclohexanone); ester solvents (e.g., ethyl acetate); lactone solvents (e.g., butyrolactone); carbonate solvents (e.g., ethylene carbonate and propylene carbonate); amine solvents (e.g., triethylamine and pyridine); nitrile solvents (e.g., acetonitrile and succinonitrile); amide solvents (e.g., N,N′-dimethylformamide, N,N′-dimethylacetamide, tetramethylurea and N-methylpyrrolidone) nitro-containing solvents (e.g., nitromethane and nitrobenzene); sulfide solvents (e.g., dimethylsulfoxide and sulfolane); and so forth. Among the above-listed aprotic solvents, amide solvents (e.g., N-methylpyrrolidone) and sulfide solvents (e.g., dimethylsulfoxide) are particularly suitable. Suitable protic solvents may likewise include, for instance, organic solvents having a phenolic hydroxyl group, such as phenolic compounds substituted with at least one halogen atom (e.g., fluorine or chlorine). Examples of such compounds include pentafluorophenol, tetrafluorophenol, o-chlorophenol, trichlorobenzene, and p-chlorophenol. Mixtures of various aprotic and/or protic solvents may also be employed.

In one particular embodiment, the solvent system may be selectively controlled in the present invention to achieve a polymer solution that is less likely to gel prior to use. In this regard, the present inventors have surprisingly discovered that a solvent system containing at least one high boiling point liquid solvent is less likely to gel over time. The boiling point of such a liquid solvent is generally low enough so that it can be removed after the solution is coated onto a substrate, but yet high enough to inhibit gelling. In this regard, the boiling point (at atmospheric pressure) of the solvent is generally about 210° C. or more, in some embodiments from about 225° C. to about 380° C., and in some embodiments, from about 240° C. to about 350° C. The solvent may also have a relatively low vapor pressure. For instance, the vapor pressure at 20° C. is typically about 50 Pascals (“Pa”) or less, in some embodiments about 20 Pa or less, and in some embodiments, from about 0.01 to about 10 Pascals. The solvent may also have a relatively high molecular weight, such as about 100 grams per mole or more, in some embodiments from about 105 grams per mole to about 250 grams per mole, and in some embodiments, from about 110 grams per mole to about 200 grams per mole.

Any of a variety of high boiling point solvents may generally be employed in the polymer solution of the present invention. Such solvents may include aprotic solvents, protic solvents, as well as mixtures thereof. Examples of suitable aprotic solvents include, for instance, organic amines (e.g., triethylenediamine (“TEDA”), hexamethylenetetramine, etc.), alkanolamines (e.g., diethanolamine (“DEA”), methyldiethanolamine (“MDEA”), triethanolamine (“TEA”), diisopropanolamine, etc.), alkylaminoalkanols (e.g., dimethylaminoethanol (“DMAE”)), as well as mixtures thereof. Tri- and/or dialkanolamines, such as methyldiethanolamine, are particularly suitable for use in the polymer solution of the present invention.

In certain embodiments of the present invention, the high boiling point solvent(s) described above may constitute the entire solvent system. Nevertheless, in most embodiments of the present invention, the high boiling point solvent(s) are used in combination with one or more other types of solvents. Any of a variety of additional solvents, including aprotic and/or protic solvents such as described above, may be employed for use in the polymer solution. In certain embodiments, the boiling point (at atmospheric pressure) of the additional solvent(s) may be relatively low, such as about 210° C. or less, in some embodiments from about 150° C. to about 208° C., and in some embodiments, from about 175° C. to about 205° C. Particularly suitable low boiling point solvents that may be employed in the polymer solution include, for instance, N-methylpyrrolidone and/or dimethylsulfoxide.

When employed in combination with other solvents, the high boiling point solvent(s) may constitute a majority portion of the solvent system and thus serve as primary solvents, or constitute a minority portion of the solvent system and thus serve as secondary solvents. In particularly suitable embodiments of the present invention, the high boiling point solvent(s) constitute from about 1 wt. % to about 45 wt. %, in some embodiments from about 2 wt. % to about 40 wt. %, and in some embodiments, from about 5 wt. % to about 35 wt. % of the solvent system, as well as from about 0.1 wt. % to about 30 wt. %, in some embodiments from about 0.5 wt. % to about 25 wt. %, and in some embodiments, from about 1 wt. % to about 20 wt. % of the entire polymer solution. In such embodiments, additional primary solvent(s) may constitute from about 55 wt. % to about 99 wt. %, in some embodiments from about 60 wt. % to about 98 wt. %, and in some embodiments, from about 65 wt. % to about 95 wt. % of the solvent system, as well as from about 40 wt. % to about 90 wt. %, in some embodiments from about 45 wt. % to about 85 wt. %, and in some embodiments, from about 50 wt. % to about 80 wt. % of the entire polymer solution.

Regardless of the particular solvents employed, the entire solvent system typically constitutes from about 60 wt. % to about 99 wt. %, in some embodiments from about 70 wt. % to about 98 wt. %, and in some embodiments, from about 75 wt. % to about 95 wt. % of the polymer solution. Aromatic polyester(s) likewise typically constitute from about 1 wt. % to about 40 wt. %, in some embodiments from about 2 wt. % to about 30 wt. %, and in some embodiments, from about 5 wt. % to about 25 wt. % of the polymer solution.

To help increase the ability of the aromatic polyester to be dispersed in solution, it may be formed into a powder in certain embodiments of the present invention using a variety of different powder formation techniques. Examples of such powder formation techniques may include wet techniques (e.g., solvent evaporation, spray drying, etc.), dry techniques (e.g., grinding, granulation, etc.), and so forth. In one particular embodiment, for example, the polyester may be ground using a jaw crusher, gyratory crusher, cone crusher, roll crusher, impact crusher, hammer crusher, cracking cutter, rod mill, ball mill, vibration rod mill, vibration ball mill, pan mill, roller mill, impact mill, discoid mill, stirring grinding mill, fluid energy mill, jet mill, etc. Jet milling, for instance, typically involves the use of a shear or pulverizing machine in which the polymer is accelerated by gas flows and pulverized by collision. Any type of jet mill design may be employed, such as double counterflow (opposing jet) and spiral (pancake) fluid energy mills. Gas and particle flow may simply be in a spiral fashion, or more intricate in flow pattern, but essentially particles collide against each other or against a collision surface. In certain embodiments, it may be desired to mill the polymer in the presence of a cryogenic fluid (e.g., dry ice, liquid carbon dioxide, liquid argon, liquid nitrogen, etc.) to produce a low-temperature environment in the system. The low-temperature environment chills the polymer below its glass transition point to facilitate grinding in a mill that applies impact or shear, such as a jet-mill.

The resulting powder generally contains microparticles formed from the aromatic polyester. The mean size of the microparticles is generally from about 0.1 to about 200 micrometers, in some embodiments from about 0.1 to about 100 micrometers, in some embodiments from about 0.1 to about 40 micrometers, in some embodiments from about 0.2 to about 30 micrometers, in some embodiments from about 0.5 to about 20 micrometers, and in some embodiments, from about 1 to about 15 micrometers. As used herein, the mean size of a microparticle may refer to its mean length, width, and/or height, and can be determined by optical microscopy as the average size of diameters measured at 2 degree intervals passing through a particle's geometric center. The microparticles may also possess a relatively low “aspect ratio” (mean length and/or width divided by the mean height). For example, the aspect ratio of the microparticles may be from about 0.4 to about 2.0, in some embodiments from about 0.5 to about 1.5, and in some embodiments, from about 0.8 to about 1.2 (e.g., about 1). In one embodiment, for example, the microparticles may have a shape that is generally spherical in nature. Regardless of the actual size and shape, however, the size distribution of the microparticles may be generally consistent throughout the powder. That is, at least about 50% by volume of the microparticles, in some embodiments at least about 70% by volume of the microparticles, and in some embodiments, at least about 90% by volume of the microparticles (e.g., 100% by volume) may have a mean size within a range of from about 0.1 to about 200 micrometers, in some embodiments from about 0.2 to about 150 micrometers, in some embodiments from about 0.5 to about 100 micrometers, and in some embodiments, from about 1 to about 50 micrometers.

The film is typically formed on a substrate, which may be metallic or non-metallic. Suitable metallic substrate may include, for instance, a metal plate or foil, such as those containing gold, silver, copper, nickel, aluminum, etc. (e.g., copper foil). Suitable non-metallic substrates may include, for instance, ceramic materials (e.g., silica, alumina, glass, etc.), polymeric materials, metalloid materials (e.g., silicon, boron, silicon, germanium, arsenic, antimony, tellurium, etc.), and so forth. Suitable polymeric materials may include, for instance, polytetrafluoroalkylenes (e.g., polytetrafluoroethylenes), polyurethanes, polyolefins, polyesters, polyimides, polyamides, etc. The substrate may also be provided in a variety of different forms, such as membranes, films, fibers, fabrics, molds, wafers, tubes, etc. For example, the substrate may have a foil-like structure in that it is relatively thin, such as having a thickness of about 500 micrometers or less, in some embodiments about 200 micrometers or less, and in some embodiments, from about 1 to about 100 micrometers. Of course, higher thicknesses may also be employed,

The film may be applied to the substrate using a variety of different techniques. In one particular embodiment, for example, a polymer solution, such as described above, is coated onto the substrate to form the film. Some suitable solution deposition techniques may include, for instance, casting, roller coating, dip coating, spray coating, spinner coating, curtain coating, slot coating, screen printing, bar coating methods, printing, etc. If desired, the solution may be filtered to remove contaminants prior to application. Once coated onto the substrate, the film may then be annealed as discussed above. For example, annealing may occur at a temperature of from about 250° C. to about 400° C., in some embodiments from about 260° C. to about 350° C., and in some embodiments, from about 280° C. to about 330° C., and for a time period ranging from about 15 minutes to about 300 minutes, in some embodiments from about 20 minutes to about 200 minutes, and in some embodiments, from about 30 minutes to about 120 minutes. During annealing, it is sometimes desirable to restrain the film at one or more locations (e.g., edges) so that it is not generally capable of physical movement. This may be accomplished in a variety of ways, such as by clamping, taping, or otherwise adhering the film to the substrate. Although not required, the film may also be subjected to an optional drying heat treatment prior to annealing to remove the solvent system, such as at a temperature of from about 50° C. to about 200° C., in some embodiments from about 80° C. to about 180° C., and in some embodiments, from about 100° C. to about 160° C., and for a time period of from about 10 minutes to about 120 hours.

Once the film is formed, it may be removed from the substrate (e.g., peeled away) for use in various different applications. Alternatively, the film may remain on the substrate to form a laminate. The laminate may have a two-layer structure containing only the film and conductive layer. Alternatively, a multi-layered laminate may be formed, such as a three-layer structure in which conductive layers are placed on both sides of a film, a five-layer structure in which films and conductive layers are alternately stacked, and so forth. Regardless of the number of layers, one benefit of the present invention is that the film can exhibit excellent adhesion to the substrate. For example, the film may exhibit an adhesion index of about 3 or more, in some embodiments about 4 or more, and in some embodiments, from about 4.5 to 5, as determined in accordance with ASTM D3359-09e2 (Test Method B). The film may also exhibit a peel strength of about 5 kPa or more, in some embodiments about 10 kPa or more, and in some embodiments, from about 12 to about 50 kPa, as determined in accordance with ASTM D1876 using the T-peel test at an angle of 90°. Due to its good adhesion properties, the laminate may be free of an additional adhesive between the film and the substrate. Nevertheless, adhesives can be employed if so desired, such as epoxy, phenol, polyester, nitrile, acryl, polyimide, polyurethane resins, etc. The film may also exhibit good electrical properties. For instance, the film may have a relatively low dielectric constant that allows it to be employed as a heat dissipating material in various electronic applications (e.g., flexible printed circuit boards). For example, the average dielectric constant may be about 5.0 or less, in some embodiments from about 0.1 to about 4.5, and in some embodiments, from about 0.2 to about 3.5, as determined by the split post resonator method at a variety of frequencies, such as from about 1 to about 15 GHz (e.g., 1, 2, or 10 GHz). The dissipation factor, a measure of the loss rate of energy, may also be relatively low, such as about 0.0060 or less, in some embodiments about 0.0050 or less, and in some embodiments, from about 0.0010 to about 0.0040, as determined by the split post resonator method at a variety of frequencies, such as from about 1 to about 15 GHz (e.g., 1, 2, or 10 GHz).

### III. Applications

The film or laminate of the present invention may be employed in a wide variety of different applications. For example the film or laminate can be employed in claddings, multi-layer print wiring boards for semiconductor package and mother boards, flexible printed circuit board, tape automated bonding, tag tape, packaging for microwave oven, shields for electromagnetic waves, probe cables, communication equipment circuits, cookware, appliances, etc. In one particular embodiment, a laminate is employed in a flexible printed circuit board that contains a metallic substrate layer and an insulating film formed as described herein. If desired, the film may be subjected to a surface treatment on a side facing the conductive layer so that the adhesiveness between the film and conductive layer is improved. Examples of such surface treatments include, for instance, corona discharge treatment, UV irradiation treatment, plasma treatment, etc.

A variety of different techniques may be employed to form a printed circuit board from such a laminate structure. In one embodiment, for example, a photo-sensitive resist is initially disposed on the metallic substrate layer and an etching step is thereafter performed to remove a portion of the layer. The resist can then be removed to leave a plurality of conductive pathways that form a circuit. If desired, a cover film may be positioned over the circuit, which may also be formed from the polymer solution of the present invention. Regardless of how it is formed, the resulting printed circuit board can be employed in a variety of different electronic components. As an example, flexible printed circuit boards may be employed in desktop computers, cellular telephones, laptop computers, small portable computers (e.g., ultraportable computers, netbook computers, and tablet computers), wrist-watch devices, pendant devices, headphone and earpiece devices, media players with wireless communications capabilities, handheld computers (also sometimes called personal digital assistants), remote controllers, global positioning system (GPS) devices, handheld gaming devices, etc. Of course, the film may also be employed in electronic components, such as described above, in devices other than printed circuit boards. For example, the film may be used to form high density magnetic tapes, wire covering materials, etc. Other types of articles, such as molded articles (e.g., containers, bottles, cookware, appliances, etc.), may also be formed using the film of the present invention.

The present invention may be better understood with reference to the following examples.

### Test Methods

Melt Viscosity: The melt viscosity (Pa-s) may be determined in accordance with ISO Test No. 11443 at 320° C. or 350° C. and at a shear rate of 400 s⁻¹ or 1000 s⁻¹ using a Dynisco 7001 capillary rheometer. The rheometer orifice (die) had a diameter of 1 mm, length of 20 mm, L/D ratio of 20.1, and an entrance angle of 180°. The diameter of the barrel was 9.55 mm±0.005 mm and the length of the rod was 233.4 mm.

Intrinsic Viscosity: The intrinsic viscosity (“IV”) may be measured in accordance with ISO-1628-5 using a 50/50 (v/v) mixture of pentafluorophenol and hexafluoroisopropanol. Each sample was prepared in duplicate by weighing about 0.02 grams into a 22 mL vial. 10 mL of pentafluorophenol (“PFP”) was added to each vial and the solvent. The vials were placed in a heating block set to 80° C. overnight. The following day 10 mL of hexafluoroisopropanol (“HFIP”) was added to each vial. The final polymer concentration of each sample was about 0.1%. The samples were allowed to cool to room temperature and analyzed using a PolyVisc automatic viscometer.

Solubility: The solubility of a polymer can be determined by adding a predetermined amount of a polymer sample to a solution containing a predetermined amount of a solvent (e.g., N-methylpyrrolidone) and heating the resulting mixture from 150° C. to 180° C. for 3 hours. The mixture is considered soluble if it forms a clear to stable dispersion that does not undergo phase separation or separate into two layers upon standing at room temperature for a period of seven (7) days. If the mixture is determined to be soluble, additional amounts of the polymer sample are tested to determine the maximum amount of polymer that can be dissolved into the solvent. Likewise, if the mixture is determined to be insoluble, lower amounts of the polymer sample are tested. The “solubility” for a given polymer is calculated by dividing the maximum weight of the polymer that can be added to a solvent without phase separation by the weight of the solvent, and then multiplying this value by 100.

Solution Viscosity: The solution viscosity may be measured at about 22° C. using a Brookfield viscometer (Model: LVDV-II+Pro, spindle #2 or #4). Viscosity measurements may be taken at spindle speeds of 0.3 to 100 rpm until reaching the maximum capacity of the spring.

Adhesion Index: The adhesion properties of a coating may be tested in accordance with ASTM D3359-09e2 (Test Method B). The adhesion index is measured on a scale from 0 to 5, with 0 representing the highest degree of adhesion and 5 representing the lowest degree of adhesion. That is, when a tape is peeled away from the coating during testing, an index of 0 means that greater than 65% of the coating was removed, an index of 1 means that 35-65% was removed, an index of 2 means that 15-35% was removed, an index of 3 means that 5-15% was removed, an index of 4 means that less than 5% was removed, and an index of 5 means that 0% was removed.

Peel Strength (T-Peel, 90°): The peel strength may be determined according to ASTM D1876 using a T-type specimen. A specimen having a size of 15 mm wide is bent at an angle of 90°, and the bent, unbonded ends of the test specimen are then clamped in the test grips and a load of a constant head speed of 10 rpm is applied. An autographic recording of the load versus the head movement or load versus distance peeled is made. The peel resistance over a specified length of the bond line after the initial peak is determined and listed as the peel strength.

Tensile Properties: The tensile properties (e.g., Young's modulus of elasticity, peak elongation, and tensile strength) may be tested according to ASTM D882-12. Measurements may be made on a test strip sample having a gauge length of 25.4 mm, thickness of 25 μm, and width of 6.35 mm. The testing temperature may be 23° C., and the testing speed may be 2.54 mm/min.

### EXAMPLE 1

A 2 L flask is charged with HNA (428.1 g), IA (351 g), 4,4′-dihydroxyldiphenylsulfone (49 g), HQ (211.1 g) and 51 mg of potassium acetate. The flask is equipped with C-shaped stirrer, thermal couple, gas inlet, and distillation head. The flask is placed under a low nitrogen purge and acetic anhydride (99.7% assay, 628.5 g) is added. The milky-white slurry is agitated at 75 rpm and heated to 140° C. over the course of 95 minutes using a fluidized sand bath. After this time, the mixture is gradually heated to 320° C. steadily over 350 minutes. Reflux is seen once the reaction exceeds 140° C. and the overhead temperature is increased to approximately 115° C. as acetic acid byproduct was removed from the system. During the heating, the mixture grows yellow and slightly more viscous and the vapor temperature gradually drops to 90° C. Once the mixture reaches 320° C., the nitrogen flow is stopped. The flask is evacuated under vacuum and the agitation is slowed to 30 rpm. As the time under vacuum progresses, the mixture grows viscous. The reaction is stopped by releasing the vacuum and stopping the heat flow to the reactor, when a predetermined torque reading is observed. The flask is cooled and the resulting polymer is recovered as a solid, dense yellow plug. Sample for analytical testing is obtained by mechanical size reduction. The melt viscosity of the sample at 320° C. is 103 Pa-s for a shear rate of 1000 s⁻¹ and 134.6 for a shear rate of 400 s⁻¹.

### EXAMPLE 2

A2 L flask is charged with HBA (310.8 g), HNA (141.1 g), IA (249.2 g), HQ (66.1 g), 4-hydroxyl phenyl sulfone (225.2 g), and 60 mg of potassium acetate. The flask is equipped with C-shaped stirrer, thermal couple, gas inlet, and distillation head. The flask is placed under a low nitrogen purge and acetic anhydride (99.7% assay, 628 g) is added. The milky-white slurry is agitated at 75 rpm and heated to 140° C. over the course of 95 minutes using a fluidized sand bath, After this time, the mixture is gradually heated to 320° C. steadily over 350 minutes. Reflux is seen once the reaction exceeds 140° C. and the overhead temperature is increased to approximately 115° C. as acetic acid byproduct was removed from the system. During the heating, the mixture grows yellow and slightly more viscous and the vapor temperature gradually drops to 90° C. Once the mixture reaches 320° C., the nitrogen flow is stopped. The flask is evacuated below 20 psi and the agitation is slowed to 30 rpm over the course of 45 minutes, As the time under vacuum progresses, the mixture grows viscous. After about 70 minutes, in the final vacuum step, a torque value of about 35 in/oz is recorded. The reaction is then stopped by releasing the vacuum and stopping the heat flow to the reactor. The flask is cooled and the resulting polymer is recovered as a solid, dense yellow-brown plug. Sample for analytical testing is obtained by mechanical size reduction. The melt viscosity of the sample at 370° C. is 77 Pa-s for a shear rate of 1000 s⁻¹ and 94 Pa-s for a shear rate of 400 s⁻¹.

### EXAMPLE 3

A 2 L flask is charged with HBA (172.7 g), HNA (235.7 g), IA (207.7 g), APAP (75.6 g) and 4-hydroxyl phenyl sulfone (187.7 g). The flask is equipped with a C-shaped stirrer, thermal couple, gas inlet, and distillation head. The flask is placed under a low nitrogen purge and acetic anhydride (99.7% assay, 628.5 g) is added. The milky-white slurry is agitated at 75 rpm and heated to 140° C. over the course of 95 minutes using a fluidized sand bath. After this time, the mixture is then gradually heated to 320° C. steadily over 350 minutes. Reflux is seen once the reaction exceeds 140° C. and the overhead temperature increases to approximately 115° C. as acetic acid byproduct is removed from the system. During the heating, the mixture grows yellow and slightly more viscous and the vapor temperature gradually drops to 90° C. Once the mixture has reached 320° C., the nitrogen flow is stopped. The flask is evacuated below 20 psi and the agitation slows to 30 rpm over the course of 45 minutes. As the time under vacuum progresses, the mixture grows viscous. After about 30 minutes, in the final vacuum step, a torque value of about 25 in/oz is recorded. The reaction is then stopped by releasing the vacuum and stopping the heat flow to the reactor. The flask is cooled and the resulting polymer is recovered as a solid, dense yellow-brown plug. Sample for analytical testing is obtained by mechanical size reduction. The melt viscosity of the sample at 320° C. is 99 Pa-s for a shear rate of 1000 s⁻¹ and 145 Pa-s for a shear rate of 400 s⁻¹.

### EXAMPLE 4

A 2 L flask is charged with HBA (241.7 g), IA (270 g), HQ (89.5 g) and 4-hydroxyl phenyl sulfone (203.3 g). The flask is equipped with a C-shaped stirrer, thermal couple, gas inlet, and distillation head. The flask is placed under a low nitrogen purge and acetic anhydride (99.7% assay, 524 g) is added. The milky-white slurry is agitated at 75 rpm and heated to 140° C. over the course of 95 minutes using a fluidized sand bath. After this time, the mixture is then gradually heated to 340° C. steadily over 280 minutes. Reflux is seen once the reaction exceeds 140° C. and the overhead temperature is increased to approximately 115° C. as acetic acid byproduct is removed from the system. During the heating, the mixture grows yellow and slightly more viscous and the vapor temperature gradually drops to 90° C. Once the mixture has reached 340° C., the nitrogen flow is stopped. The flask is evacuated below 20 psi and the agitation slows to 30 rpm over the course of 45 minutes. As the time under vacuum progresses, the mixture grows viscous. After about 15 minutes, in the final vacuum step, a torque value of about 1 in/oz is recorded. The reaction is then stopped by releasing the vacuum and stopping the heat flow to the reactor. The flask is cooled and the resulting polymer is recovered as a solid, dense yellow-brown plug. Sample for analytical testing is obtained by mechanical size reduction. The melt viscosity of the sample at 350° C. is 137 Pa-s (shear rate of 1000 s⁻¹) and 152 Pa-s (shear rate of 400 s⁻¹).

### EXAMPLE 5

A 2 L flask is charged with HBA (241.7 g), IA (270 g), HQ (123.9 g) and 4-hydroxyl phenyl sulfone (123.9 g). The flask is equipped with a C-shaped stirrer, thermal couple, gas inlet, and distillation head. The flask is placed under a low nitrogen purge and acetic anhydride (99.7% assay, 524 g) is added. The milky-white slurry is agitated at 75 rpm and heated to 140° C. over the course of 95 minutes using a fluidized sand bath. After this time, the mixture is then gradually heated to 340° C. steadily over 280 minutes. Reflux is seen once the reaction exceeds 140° C. and the overhead temperature is increased to approximately 115° C. as acetic acid byproduct is removed from the system. During the heating, the mixture grows yellow and slightly more viscous and the vapor temperature gradually drops to 90° C. Once the mixture has reached 340° C., the nitrogen flow is stopped. The flask is evacuated below 20 psi and the agitation slows to 30 rpm over the course of 45 minutes. As the time under vacuum progresses, the mixture grows viscous. After about 40 minutes, in the final vacuum step, a torque value of about 40 in/oz is recorded. The reaction is then stopped by releasing the vacuum and stopping the heat flow to the reactor. The flask is cooled and the resulting polymer is recovered as a solid, dense yellow-brown plug. Sample for analytical testing is obtained by mechanical size reduction. The melt viscosity of the sample at 370° C. is 260 Pa-s (shear rate of 1000 s⁻¹) and 353 Pa-s (shear rate of 400 s^{31 1}).

### EXAMPLE 6

The ability to form a film from the polymers described herein was demonstrated. More particularly, the polymer of Example 1 was solid-state polymerized for six (6) hours and then dissolved in a solvent system containing N-methylpyrrolidone. Once formed, the solution was then coated onto a copper sheet having a thickness of approximately 80 micrometers, dried at 100° C. for 60 minutes, and subsequently annealed at 290° C. for 1 hour. After annealing, the LCP coating began to delaminate and was thus peeled away from the copper sheet as a film. The resulting film had a thickness of about 25 micrometers and was tested for tensile strength, elongation, and Young's modulus, the results of which are set forth below in Table 1.

TABLE 1
Mechanical Properties of Film

| | Machine | Cross-Machine | |
|---|---|---|---|
| | Direction | Direction | Ratio of MD/CD |
| | (“MD”) | (“CD”) | Tensile Property |
| Tensile Strength (MPa) | 117 | 111 | 1.05 |
| Peak Elongation (%) | 17 | 16 | 1.06 |
| Young's Modulus (MPa) | 2,200 | 2,200 | 1.00 |

As indicated, the mechanical properties of the annealed film were substantially isotropic in nature.

### EXAMPLE 7

The ability to form films from the polymers described herein was demonstrated. More particularly, the polymer of Example 1 was solid-state polymerized for six (6) hours and then dissolved in a solvent system containing N-methylpyrrolidone. Once formed, the solution was then coated onto a copper sheet having a thickness of approximately 25 micrometers, dried at 100° C. for 60 minutes, and subsequently annealed at various times and temperatures as indicated below. After annealing, the brittleness of the samples was qualitatively determined by folding the samples edge to edge at an angle of 180°. The results are set forth below in Table 2.

TABLE 2
Properties of Annealed Films

| | Annealing temp. | | |
|---|---|---|---|
| Sample | (° C.) | Annealing duration (hr) | 180° Folding Test |
| 1 | 260 | 1.0 | Fail |
| 2 | 280 | 0.5 | Fail |
| 3 | 280 | 1.0 | Pass |
| 4 | 290 | 0.5 | Fail |
| 5 | 290 | 1.0 | Pass |
| 6 | 290 | 2.0 | Pass |
| 7 | 330 | 2.0 | Pass |
| 8 | 345 | 2.0 | Fail |

As indicated, a range of different annealing temperatures and times were able to achieve sufficient robustness to pass the 180°-folding test without showing any cracking and delamination. The mechanical properties and peel strength of Sample 5 were also tested. The results are set forth below in Table 3.

TABLE 3
Mechanical Properties of Sample 5

| | Machine | Cross-Machine | |
|---|---|---|---|
| | Direction | Direction | Ratio of MD/CD |
| | (“MD”) | (“CD”) | Tensile Property |
| Tensile Strength (MPa) | 92.6 | 87.4 | 1.06 |
| Elongation (%) | 10.9 | 12.7 | 0.86 |
| Young's Modulus (MPa) | 2,500 | 2,300 | 1.09 |

| | |
|---|---|
| Peel Strength | 18.6 |
| (T-Peel, 90°) (kPa) | |

As indicated, the mechanical properties of the annealed film were substantially isotropic in nature.

These and other modifications and variations of the present invention may be practiced by those of ordinary skill in the art, without departing from the spirit and scope of the present invention. In addition, it should be understood that aspects of the various embodiments may be interchanged both in whole or in part. Furthermore, those of ordinary skill in the art will appreciate that the foregoing description is by way of example only, and is not intended to limit the invention so further described in such appended claims.

What is claimed is:

1. A film comprising an aromatic polyester that contains aromatic biphenyl repeating units having the following general Formula I: 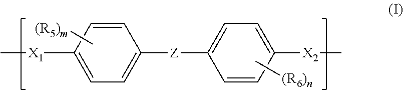
wherein,
R₅ and R₆ are independently halo, haloalkyl, alkyl, alkenyl, aryl, heteroaryl, cycloalkyl, or heterocyclyl;
m and n are independently from 0 to 4;
X₁ and X₂ are independently O, C(O), NH, C(O)HN, or NHC(O); and
Z is O or SO₂,
wherein the film is annealed, and wherein the film exhibits a tensile property value in the machine direction and the cross-machine direction, the ratio of the tensile property value in the machine direction to the tensile property value in the cross-machine direction being from about 0.7 to about 1.3.

2. The film of claim 1, wherein the ratio is from about 0.9 to about 1.1.

3. The film of claim 1, wherein the tensile property value is peak elongation.

4. The film of claim 1, wherein the tensile property value is Young's modulus of elasticity.

5. The film of claim 1, wherein the tensile property value is tensile strength.

6. The film of claim 1, wherein the film exhibits a peak elongation value in the machine direction and/or cross-machine direction of about 5% or more.

7. The film of claim 1, wherein the film exhibits a Young's modulus of elasticity in the machine direction and/or cross-machine direction of from about 500 to about 10,000 MPa.

8. The film of claim 1, wherein the film exhibits a tensile strength in the machine direction and/or cross-machine direction of from about 15 to about 300 Megapascals.

9. The film of claim 1, wherein the film has a thickness of about 500 micrometers or less.

10. The film of claim 1, wherein the aromatic biphenyl repeating units constitute from about 5 mol. % to about 50 mol. % of the aromatic polyester.

11. The film of claim 1, wherein the aromatic polyester contains from about 1 mol. % to about 70 mol. % of aromatic hydroxycarboxylic repeating units and from about 5 mol. % to about 60 mol. % of aromatic dicarboxylic acid repeating units.

12. The film of claim 11, wherein the aromatic dicarboxylic acid repeating units are derived from terephthalic acid, isophthalic acid, or a combination thereof, and wherein the aromatic hydroxcarboxylic acid repeating units are derived from 4-hydroxybenzoic acid, 2-hydroxy-6-naphthoic acid, or a combination thereof.

13. The film of claim 11, wherein the polyester further comprises one or more repeating units derived from an aromatic diol, aromatic amide, aromatic amine, or a combination thereof.

14. The film of claim 11, wherein ring A and ring B are 1,4-phenylene.

15. The film of claim 11, wherein m and n Formula I are 0.

16. The film of claim 11, wherein X₁, X₂, or both are O or NH.

17. The film of claim 1, wherein Z is SO₂.

18. The film of claim 17, wherein the biphenyl repeating units are derived from 4-(4-hydroxyphenyl)-sulfonylphenol, 4-(4-aminophenyl)sulfonylphenol, 4-(4-aminophenyl)sulfonylaniline, or a combination thereof.

19. The film of claim 1, wherein Z is O.

20. The film of claim 19, wherein the biphenyl repeating units are derived from 4-(4-aminophenoxy)phenol, 4-(4-hydroxyphenoxy)-phenol, 4-(4-aminophenoxy)aniline, 4-(4-formylphenoxy)benzaldehyde, 4-(4-carbamoylphenoxy)benzamide, or a combination thereof.

21. The film of claim 1, wherein the polyester is wholly aromatic.

22. A laminate comprising a substrate coated with the film of claim 1.

23. A method for forming a film, the method comprising:
coating a substrate with a polymer solution that includes an aromatic polyester and a solvent system to form the film, the aromatic polyester containing aromatic biphenyl repeating units having the following general Formula I: 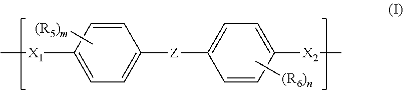
wherein,
R₅ and R₆ are independently halo, haloalkyl, alkyl, alkenyl, aryl, heteroaryl, cycloalkyl, or heterocyclyl;
m and n are independently from 0 to 4;
X₁ and X₂ are independently O, C(O), NH, C(O)HN, or NHC(O); and
Z is O or SO₂; and
thereafter, annealing the film.

24. The method of claim 23, wherein the solvent system includes N-methylpyrrolidone, dimethylsulfoxide, or a combination thereof.

25. The method of claim 24 wherein the solvent system further contains a solvent having a boiling point of about 210° C. or more at atmospheric pressure.

26. The method of claim 25, wherein annealing occurs at a temperature of from about 250° C. to about 400° C. for a time period ranging from about 15 minutes to about 300 minutes.

27. The method of claim 23, wherein the film is dried prior to annealing at a temperature of from about 50° C. to about 200° C.

28. The method of claim 26, further comprising peeling the annealed film away from the substrate.
